(19) United States
(12) Patent Application Publication
(10) Pub. No.: US 2026/0370225 A1
(43) Pub. Date: Nov. 19, 2026

(54) COMPONENT CIRCUIT AND ELECTRONIC DEVICE

(71) Applicant: InnoLux Corporation, Miao-Li County (TW)

(72) Inventors: Chin-Lung TING, Miao-Li County (TW); Shih-Siang YAN, Miao-Li County (TW); Yi-Hung LIN, Miao-Li County (TW); Sheng-Hui CHEN, Miao-Li County (TW)

(21) Appl. No.: 19/645,672

(22) Filed: Apr. 13, 2026

(30) Foreign Application Priority Data
May 16, 2025 (CN) 202510633415.0

(51) Int. Cl. H03K 17/687

(52) U.S. Cl. CPC H03K 17/6871

(57) ABSTRACT

A component circuit includes a first transistor, a second transistor and an electronic component. The first transistor includes a first gate. The second transistor includes a second gate. The electronic component is electrically connected to the first transistor and the second transistor. The first gate and the second gate are respectively configured to receive a first signal and a second signal. When the first transistor changes from the turned-on state to the turned-off state according to the first signal, the second transistor is in the turned-on state. After the first transistor is in the turned-off state, the second transistor changes from the turned-on state to the turned-off state according to the second signal.

### CROSS REFERENCE TO RELATED APPLICATIONS

This application claims priority of China Patent Application No. 202510633415.0, filed on May 16, 2025, the entirety of which is incorporated by reference herein.

### TECHNICAL FIELD

The disclosure relates to a component circuit, and in particular, it relates to a component circuit and an electronic device for reducing a feedthrough voltage.

### BACKGROUND

In a conventional component design, two or more transistors may be connected in series to serve as a component switch. However, the stray capacitance and load of transistors also increase as the number increases, causing the stray capacitance and storage capacitance to form a coupling effect when the component is turned off, resulting in a voltage drop across the storage capacitance, which is the so-called feedthrough effect. Therefore, a new design is needed to solve the problem described above.

### BRIEF SUMMARY

An embodiment of the disclosure provides a component circuit, which includes first and second transistors and an electronic component. The first and second transistors include first and second gates. The electronic component is electrically connected to the first and second transistors. The first and second gates respectively receive first and second signals. When the first transistor changes from the turned-on state to the turned-off state according to the first signal, the second transistor is in the turned-on state. After the first transistor is in the turned-off state, the second transistor changes from the turned-on state to the turned-off state according to the second signal.

An embodiment of the disclosure provides an electronic device, which includes first, second and third signal lines and a component circuit. The first signal line provides a first signal and extends in a first direction. The second signal line provides a second signal, extends in the first direction and is adjacent to the first signal line. The third signal line extends in a second direction. The second direction is different from the first direction. The component circuit is electrically connected to the first, second and third signal lines. The component circuit includes first and second transistors and an electronic component. The first and second transistors include first and second gates. The electronic component is electrically connected to the first and second transistors. The first and second gates respectively receive the first and second signals. When the first transistor changes from the turned-on state to the turned-off state according to the first signal, the second transistor is in the turned-on state. After the first transistor is in the turned-off state, the second transistor changes from the turned-on state to the turned-off state according to the second signal.

### BRIEF DESCRIPTION OF THE DRAWINGS

The disclosure can be fully understood by reading the subsequent detailed description and examples with references made to the accompanying drawings, wherein:

FIG. 1 is a schematic view of an electronic device according to an embodiment of the disclosure;

FIG. 2 is a schematic view of a component circuit according to an embodiment of the disclosure;

FIG. 3 is a waveform diagram of a first signal and a second signal according to an embodiment of the disclosure;

FIG. 4 is a schematic view of a component circuit according to an embodiment of the disclosure;

FIG. 5 is a schematic view of a component circuit according to an embodiment of the disclosure;

FIG. 6 is a waveform diagram of a first signal according to an embodiment of the disclosure;

FIG. 7 is a schematic view of a component circuit according to an embodiment of the disclosure; and

FIG. 8 is a waveform diagram of a first signal, a second signal, a third signal and a fourth signal according to an embodiment of the disclosure.

### DETAILED DESCRIPTION

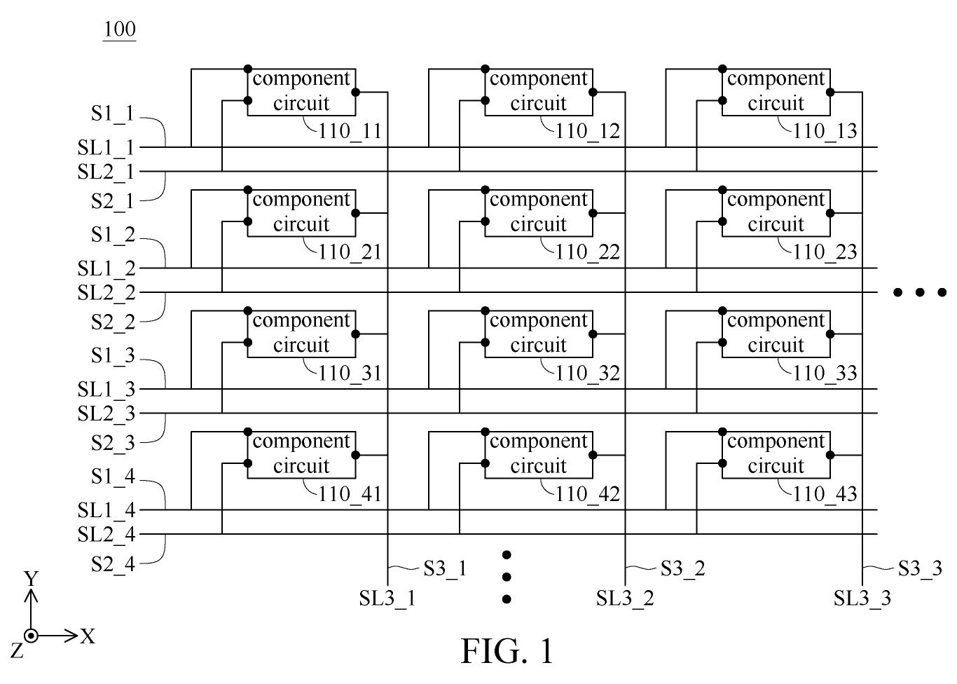

FIG. 1 is a schematic view of an electronic device according to an embodiment of the disclosure. The electronic device 100 may be applied to a product such as a display device and an antenna. The electronic device 100 may include first, second and third signal lines SL1_1, SL2_1 and SL3_1 and a component circuit 110_11. The first and second signal lines SL1_1 and SL2_1 may provide first and second signals S1_1 and S2_1 and extend in a first direction. The second signal line SL2_1 is adjacent to the first signal line SL1_1. The third signal line SL3_1 may provide a third signal S3_1 and extend in a second direction. The second direction is different from the first direction. In some embodiments, the first direction may be a X direction, and the second direction may be a Y direction. The component circuit 110_11 may be electrically connected to the first, second and third signal lines SL1_1, SL2_1 and SL3_1.

The electronic device 100 may further include first signal lines SL1_2, SL1_3 and SL1_4, second signal lines SL2_2, SL2_3 and SL2_4, third signal lines SL3_2 and SL3_3 and component circuits 110_12, 110_13, 110_21, 110_22, 110_23, 110_31, 110_32, 110_33, 110_41, 110_42 and 110_43. The first signal lines SL1_2, SL1_3 and SL1_4 may provide first signals S1_2, S1_3 and S1_4 and extend in the first direction. The second signal lines SL2_2, SL2_3 and SL2_4 may provide second signals S2_2, S2_3 and S2_4, extend in the first direction and are adjacent to the first signal lines SL1_2, SL1_3 and SL1_4. In addition, the first and second signal lines SL1_1~SL1_4 and SL2_1~SL2_4 may be alternately arranged in the second direction. The third signal lines SL3_2 and SL3_3 may provide third signals S3_2 and S3_3 and extend in the second direction.

The component circuit 110_12 may be electrically connected to the first, second and third signal lines SL1_1, SL2_1 and SL3_2. The component circuit 110_13 may be electrically connected to the first, second and third signal line SL1_1, SL2_1 and SL3_3. The component circuit 110_21 may be electrically connected to the first, second and third signal lines SL1_2, SL2_2 and SL3_1. The component circuit 110_22 may be electrically connected to the first, second and third signal lines SL1_2, SL2_2 and SL3_2. The component circuit 110_23 may be electrically connected to the first, second and third signal lines SL1_2, SL2_2 and SL3_3.

The component circuit 110_31 may be electrically connected to the first, second and third signal lines SL1_3, SL2_3 and SL3_1. The component circuit 110_32 may be electrically connected to the first, second and third signal lines SL1_3, SL2_3 and SL3_2. The component circuit 110_33 may be electrically connected to the first, second and third signal lines SL1_3, SL2_3 and SL3_3. The component circuit 110_41 may be electrically connected to the first, second and third signal lines SL1_4, SL2_4 and SL3_1. The component circuit 110_42 may be electrically connected to the first, second and third signal lines SL1_4, SL2_4 and SL3_2. The component circuit 110_43 may be electrically connected to the first, second and third signal lines SL1_4, SL2_4 and SL3_3.

The component circuits 110_11~110_43 may be arranged in a matrix, as shown in FIG. 1. When the electronic device 100 is applied to the display device, each of the component circuits 110_11~110_43 may be a pixel circuit. Each of the first and second signal lines SL1_1~SL1_4 and SL2_1~SL2_4 may be a gate signal line, and each of the first and second signals S1_1~S1_4 and S2_1~S2_4 may be a gate signal. Each of the third signal lines SL3_1~SL3_3 may be a data signal line, and each of the third signals S3_1~S3_3 may be a data signal.

In the embodiment, the internal components of the component circuits 110_11~110_43 and the operations thereof may be the same. For the convenience of explanation, the following description will be made by taking the component circuit 110_11 as an example. In FIG. 1, the number of the first, second and third signal lines and the component circuit included in the electronic device 100 is an implementation example of the disclosure and is not used to limit the aspects of the electronic device 100 of the disclosure. In other embodiments, the number of the first, second and third signal lines and the component circuit included in the electronic device 100 may be other numbers, the configuration relationship of other numbers of the first, second and third signal lines and the component circuit and the coupling manner thereof may refer to the description of the embodiment of FIG. 1, and the description thereof is not limited thereto.

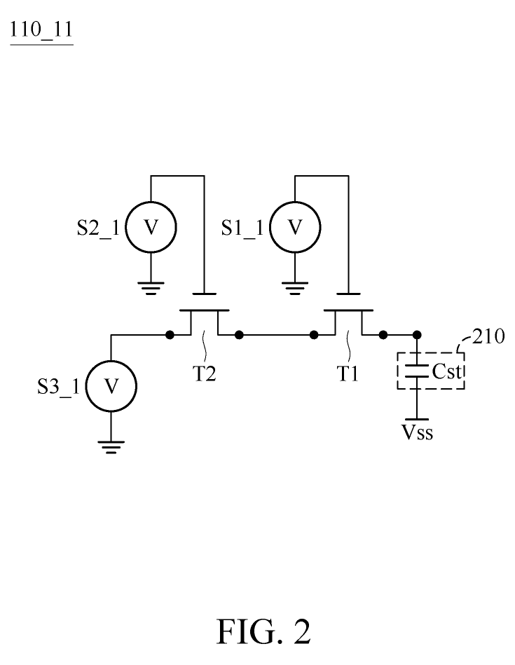

The component circuit 110_11 may include first and second transistors T1 and T2 and an electronic component 210, as shown in FIG. 2. The first transistor T1 may include a first gate, a first drain and a first source. The second transistor T2 may include a second gate, a second drain and a second source. Each of the first and second transistors T1 and T2 may be a thin film transistor (TFT). Each of the first and second transistors T1 and T2 may be an N-type transistor. In other embodiments, each of the first and second transistors T1 and T2 may be a P-type transistor or another suitable transistor.

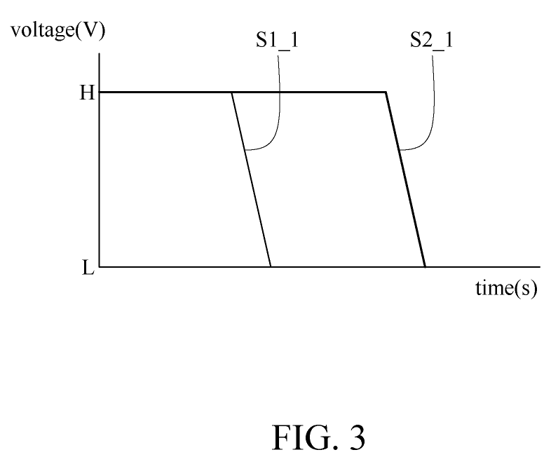

The electronic component 210 may be electrically connected to the first and second transistors T1 and T2. The electronic component 210 may include first and second terminals. The electronic component 210 may include a capacitor Cst. In other embodiments, the electronic component 210 may include another suitable component for storing energy. The first and second gates of the first and second transistors T1 and T2 may be electrically connected to the first and second signal line SL1_1 and SL2_1 and receive the first and second signals S1_1 and S2_1, as shown in FIG. 3. The first signal S1_1 may be different from the second signal S2_1.

The second drain of the second transistor T2 may be electrically connected to the first drain of the first transistor T1. The second source of the second transistor T2 may be electrically connected to the third signal line SL3_1 and receive the third signal S3_1. The first terminal of the electronic component 210 may be electrically connected to the first drain of the first transistor T1. Furthermore, the electronic component 210 may be directly electrically connected to the first transistor T1 and be electrically connected to the second transistor T2 through the first transistor T1. The second terminal of the electronic component 210 may be electrically connected to a reference voltage Vss. The first and second transistors T1 and T2 may be electrically connected in series. The first transistor T1 may be coupled between the electronic component 210 and the second transistor T2. The reference voltage Vss may be a ground voltage or a low voltage level.

As shown in FIG. 3, when the first and second signals S1_1 and S2_1 are a high voltage level H, the first and second transistors T1 and T2 are turned on. At this time, the third signal S3_1 may be transmitted to the electronic component 210 through the second and first transistors T2 and T1, so as to charge the electronic component 210.

Then, when the first signal S1_1 changes from the high voltage level H to a low voltage level L and the second signal S2_1 is still the high voltage level H, the first transistor T1 changes from being turned on to being turned off, and the second transistor T2 is still turned on. That is, when the first transistor T1 changes from the turned-on state to the turned-off state according to the first signal S1_1, the second transistor T2 may be in the turned-on state. Afterward, when the first signal S1_1 is the low voltage level L and the second signal S2_1 changes from the high voltage level H to the low voltage level L, the first transistor T1 is still turned off, and the second transistor T2 changes from being turned on to being turned off. That is, after the first transistor T1 is in the turned-off state, the second transistor T2 may changes from the turned-on state to the turned-off state according to the second signal S2_1. Therefore, it may effectively reduce the feedthrough voltage generated when the transistor is turned off.

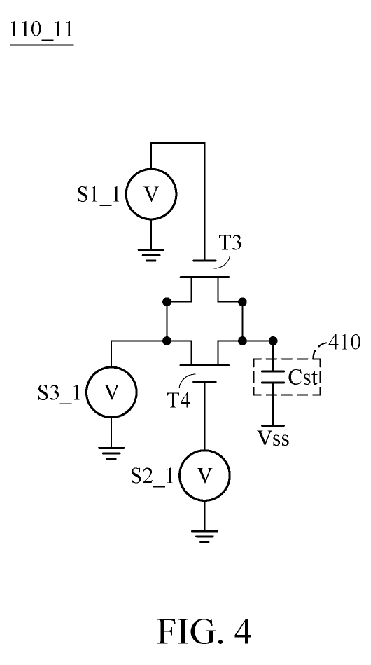

The component circuit 110_11 may include first and second transistors T3 and T4 and an electronic component 410, as shown in FIG. 4. The first transistor T3 may include a first gate, a first drain and a first source. The second transistor T4 may include a second gate, a second drain and a second source. Each of the first and second transistors T3 and T4 may be a thin film transistor. Each of the first and second transistors T3 and T4 may be an N-type transistor. In other embodiments, each of the first and second transistors T3 and T4 may be a P-type transistor or another suitable transistor.

The electronic component 410 may be electrically connected to the first and second transistors T3 and T4. The electronic component 410 may include first and second terminals. The electronic component 410 may include a capacitor Cst. In other embodiments, the electronic component 410 may include another suitable component for storing energy. The first and second gates of the first and second transistors T3 and T4 may be electrically connected to the first and second signal lines SL1_1 and SL2_1 and receive the first and second signals S1_1 and S2_1, as shown in FIG. 3. In the embodiment, the first signal S1_1 may be different from the second signal S2_1.

The first source of the first transistor T3 may be electrically connected to the second source of the second transistor T4 and the third signal line SL3_1 and receive the third signal S3_1. The first drain of the first transistor T3 may be electrically connected to the second drain of the second transistor T4. The first terminal of the electronic component 410 may be electrically connected to the first and second drains of the first and second transistors T3 and T4. That is, the first and second transistors T3 and T4 may be electrically connected in parallel. The second terminal of the electronic component 410 may be electrically connected to a reference voltage Vss. In some embodiments, the reference voltage Vss may be a ground voltage or a low voltage level.

As shown in FIG. 3, when the first and second signals S1_1 and S2_1 are a high voltage H, the first and second transistors T3 and T4 are turned on. At this time, the third signal S3_1 may be transmitted to the electronic component 410 through the second and first transistors T4 and T3, so as to charge the electronic component 410. Then, when the first signal S1_1 changes from the high voltage level H to a low voltage level L and the second signal S2_1 is still the high voltage level H, the first transistor T3 changes from being turned on to being turned off, and the second transistor T4 is still turned on. That is, when the first transistor T3 changes from the turned-on state to the turned-off state according to the first signal S1_1, the second transistor T4 may be in the turned-on state. Afterward, when the first signal S1_1 is the low voltage level L and the second signal S2_1 changes from the high voltage level H to the low voltage level L, the first transistor T3 is still turned off, and the second transistor T4 changes from being turned on to being turned off. That is, after the first transistor T3 is in the turned-off state, the second transistor T4 may changes from the turned-on state to the turned-off state according to the second signal S2_1. Therefore, it may effectively reduce the feedthrough voltage generated when the transistor is turned off.

In the embodiment of FIG. 4, the first transistor T3 may first change from the turned-on state to the turned-off state according to the first signal S1_1, and after the first transistor T3 is in the turned-off state, the second transistor T4 then changes from the turned-on state to the turned-off state according to the second signal S2_1. In other embodiments, the first signal S1_1 and the second signal S2_1 may be exchanged, i.e., the second transistor T4 may first change from the turned-on state to the turned-off state according to the second signal S2_1, and after the second transistor T4 is in the turned-off state, the first transistor T3 then changes from the turned-on state to the turned off state according to the first signal S1_1, which may also achieve the same technical effect.

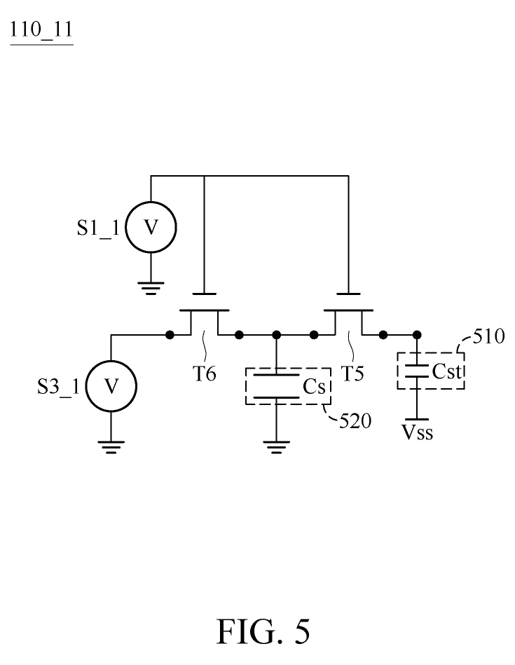

The component circuit 110_11 may include first and second transistors T5 and T6 and electronic components 510 and 520, as shown in FIG. 5. The first transistor T5 may include a first gate, a first drain and a first source. The second transistor T6 may include a second gate, a second drain and a second source. Each of the first and second transistors T5 and T6 may be a thin film transistor. Each of the first and second transistors T5 and T6 may be an N-type transistor. In other embodiments, each of the first and second transistors T5 and T6 may be a P-type transistor or another suitable transistor. The electronic component 510 may be electrically connected to the first and second transistors T5 and T6. The electronic component 510 may include first and second terminals. The electronic component 510 may include a capacitor Cst.

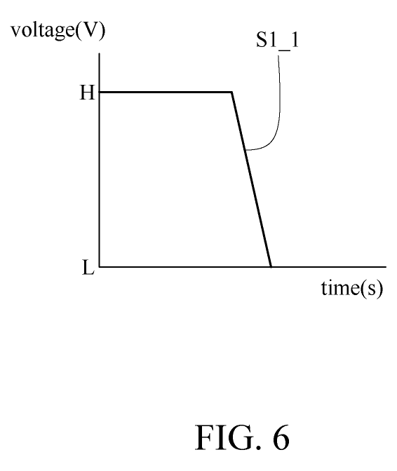

The electronic component 520 may be electrically connected to a node between the first and second transistors T5 and T6. The electronic component 520 may include first and second terminals. The electronic component 520 may include a capacitor Cs. In other embodiments, each of the electronic components 510 and 520 may include another suitable component for storing energy. The capacitance value of the capacitor Cs is different from the capacitance value of the capacitor Cst, for example, the capacitance value of the capacitor Cs is less than the capacitance value of the capacitor Cst. The first and second gates of the first and second transistors T5 and T6 may be electrically connected to the first signal line SL1_1 and receive the first signal S1_1, as shown in FIG. 6.

The second drain of the second transistor T6 may be electrically connected to the first source of the first transistor T5. The second source of the second transistor T6 may be electrically connected to the third signal line SL3_1 and receive the third signal S3_1. The first terminal of the electronic component 510 may be electrically connected to the first drain of the first transistor T5. Furthermore, the electrically component 510 may be directly electrically connected to the first transistor T5 and be electrically connected to the second transistor T6 through the first transistor T5. The second terminal of the electronic component 510 may be electrically connected to a reference voltage Vss. That is, the first and second transistors T5 and T6 may be electrically connected in series. In addition, the first transistor T5 may be coupled between the electronic component 510 and the second transistor T6. The reference voltage Vss may be a ground voltage or a low logic level.

The first terminal of the electronic component 520 may be electrically connected to the first source of the first transistor T5 and the second drain of the second transistor T6. Furthermore, the first terminal of the electronic component 520 may be directly electrically connected to the first source of the first transistor T5 and the second drain of the second transistor T6. The second terminal of the electronic component 520 may be electrically connected to a ground terminal. As shown in FIG. 6, when the first signal S1_1 is a high voltage level H, the first and second transistors T5 and T6 are turned on. At this time, the third signal S3_1 may be transmitted to the electronic component 510 through the second and first transistors T6 and T5, so as to charge the electronic component 510. Then, when the first signal S1_1 changes from the high voltage level H to a low voltage level L, the first and second transistors T5 and T6 change from being turned on to being turned off. That is, the first and second transistors T5 and T6 may change from the turned-on state to the turned-off state according to the first signal S1_1. At this time, the stray capacitance coupling between the first and second transistors T5 and T6 may be suppressed through the electronic component 520. Therefore, it may effectively reduce the feedthrough voltage generated when the transistor is turned off.

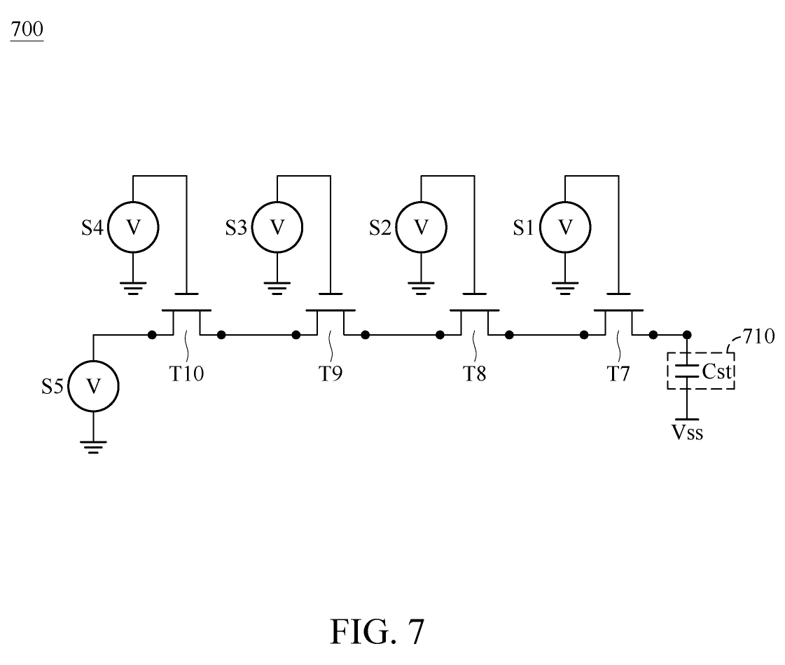

FIG. 7 is a schematic view of a component circuit according to an embodiment of the disclosure. The component circuit 700 may include first, second, third and fourth transistors T7, T8, T9 and T10 and an electronic component 710. The first transistor T7 may include a first gate, a first drain and a first source. The second transistor T8 may include a second gate, a second drain and a second source. The third transistor T9 may include a third gate, a third drain and a third source. The fourth transistor T10 may include a fourth gate, a fourth drain and a fourth source. Each of the first, second, third and the fourth transistors T7, T8, T9 and T10 may be a thin film transistor. In the embodiment, each of the first, second, third and fourth transistors T7, T8, T9 and T10 may be an N-type transistor. In other embodiments, each of the first, second, third and fourth transistors T7, T8, T9 and T10 may be a P-type transistor or another suitable transistor.

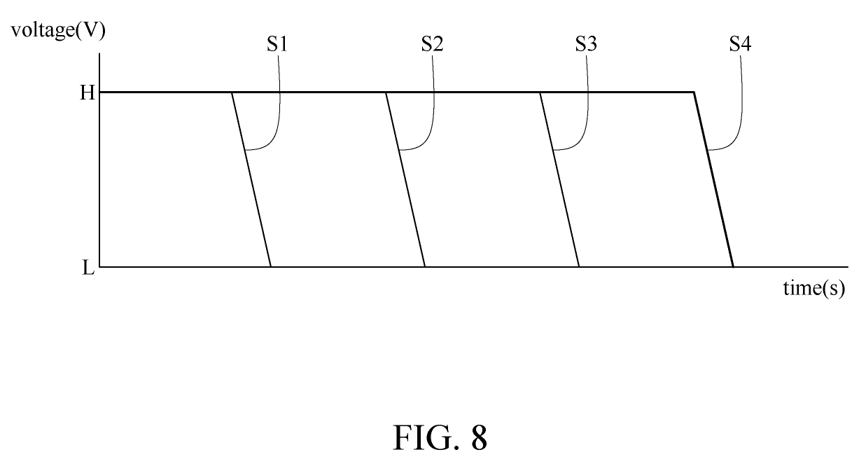

The electronic component 710 may be electrically connected to the first, second, third and fourth transistors T7, T8, T9 and T10. The electronic component 710 may include first and second terminals. The electronic component 710 may include a capacitor Cst. In other embodiments, the electronic component 710 may include another suitable component for storing energy. The first, second, third and fourth gates of the first, second, third and fourth transistors T7, T8, T9 and T10 may receive the first, second, third and fourth signals S1, S2, S3 and S4. As shown in FIG. 8, the first, second, third and fourth signals S1, S2, S3 and S4 may be different. The second, third and fourth drains of the second, third and fourth transistors T8, T9 and T10 may be electrically connected to the first, second and third sources of the first, second and third transistors T7, T8 and T9. The fourth source of the fourth transistor T10 may receive the fifth signal S5. In some embodiments, each of the first, second, third and fourth signals S1, S2, S3 and S4 may be a gate signal, and the fifth signal S5 may be a data signal. The first and second terminals of the electronic component 710 may be electrically connected to the first drain of the first transistor T7 and a reference voltage Vss. That is, the first, second, third and fourth transistors T7, T8, T9 and T10 may be electrically connected in series. In some embodiments, the reference voltage Vss may be a ground voltage or a low voltage level.

As shown in FIG. 8, when the first, second, third and fourth signals S1, S2, S3 and S4 are a high voltage level H, the first, second, third and fourth transistors T7, T8, T9 and T10 are turned on. At this time, the fifth signal S5 may be transmitted to the electronic component 710 through the fourth, third, second and first transistors T10, T9, T8 and T7, so as to charge the electronic component 710. Then, when the first signal S1 changes from the high voltage level H to a low voltage level L and the second, third and fourth signals S2, S3 and S4 are still the high voltage level H, the first transistor T7 changes from being turned on to being turned off, and the second, third and fourth transistors T8, T9 and T10 are still turned on. That is, when the first transistor T7 changes from the turned-on state to the turned-off state according to the first signal S1, the second, third and fourth transistors T8, T9 and T10 may be in the turned-on state.

Afterward, when the first signal S1 is the low voltage level L, the second signal S2 changes from the high voltage H to the low voltage L and the third and fourth signals S3 and S4 are still the high voltage level H, the first transistor T7 is still turned off, the second transistor T8 changes from being turned on to being turned off, and the third and fourth transistors T9 and T10 are still turned on. That is, after the first transistor T7 is in the turned-off state, the second transistor T8 may change from the turned-on state to the turned-off state according to the second signal S2. Then, when the first and second signals S1 and S2 are the low voltage level L, the third signal S3 changes from the high voltage level H to the low voltage level L and the fourth signal S4 is still the high voltage level H, the first and second transistors T7 and T8 are still turned off, the third transistor T9 changes from being turned on to being turned off, and the fourth transistor T10 is still turned on. That is, after the first and second transistors T7 and T8 are in the turned-off state, the third transistor T9 may change from the turned-on state to the turned-off state according to the third signal S3.

Afterward, when the first, second and third signals S1, S2 and S3 are the low voltage level L and the fourth signal S4 changes from the high voltage level H to the low voltage level L, the first, second and third transistors T7, T8 and T9 are still turned off, and the fourth transistor T10 changes from being turned on to being turned off. That is, after the first, second and third transistors T7, T8 and T9 are in the turned-off state, the fourth transistor T10 may change from the turned-on state to the turned-off state according to the fourth signal S4. Therefore, it may effectively reduce the feedthrough voltage generated when the transistor is turned off.

In FIG. 8, the first transistor T7 may first change from the turned-on state to the turned-off state according to the first signal S1, and after the first transistor T7 is in the turned-off state, the second, third and the fourth transistors T8, T9 and T10 may then sequentially change from the turned-on state to the turned-off state according to the second, third and fourth signals S2, S3 and S4. In some embodiments, the second, third and fourth signals S2, S3 and S4 may be exchanged, i.e., after the first transistor T7 is in the turned-off state, the turn-off sequence of the second, third and fourth transistors T8, T9 and T10 may be: the second, fourth and third transistors T8, T10 and T9, or the third, second and fourth transistors T9, T8 and T10, or the third, fourth and second transistors T9, T10 and T8, or the fourth, second and third transistors T10, T8 and T9, or the fourth, third and second transistors T10, T9 and T8, which may also achieve the same technical effect.

In some embodiments, the second, third and fourth signals S2, S3 and S4 may be the same, i.e., after the first transistor T7 is in the turned-off state, the second, third and fourth transistors T8, T9 and T10 may be turned off at the same time, which may also achieve the same technical effect. When the second, third and fourth signals S2, S3 and S4 are the same, the second, third and fourth transistors T8, T9 and T10 may be electrically connected to the same signal line, and there is no need to use three signal lines to respectively electrically connect the second, third and fourth transistors T8, T9 and T10. Therefore, it may save the number of signal lines, or reduce the circuit layout space.

In FIG. 8, the first, second, third and fourth transistors T7, T8, T9 and T10 may be electrically connected in series. The first, second, third and fourth transistors T7, T8, T9 and T10 may also be electrically connected in parallel, similar to the connection manner of the component circuit 110_11 in FIG. 4, which may also achieve the same technical effect.

In summary, according to the component circuit and the electronic device disclosed by the embodiments of the disclosure, when the first transistor changes from the turned-on state to the turned-off state according to the first signal, the second transistor is in the turned-on state. After the first transistor is in the turned-off state, the second transistor changes from the turned-on state to the turned-off state according to the second signal. Therefore, it may effectively reduce the feedthrough voltage generated when the transistor is turned off.

While the disclosure has been described by way of example and in terms of the preferred embodiments, it should be understood that the disclosure is not limited to the disclosed embodiments. On the contrary, it is intended to cover various modifications, combinations, and similar arrangements (as would be apparent to those skilled in the art). Therefore, the scope of the appended claims should be accorded the broadest interpretation to encompass all such modifications, combinations, and similar arrangements.

What is claimed is:

1. A component circuit, comprising:
a first transistor, comprising a first gate;
a second transistor, comprising a second gate; and
an electronic component, electrically connected to the first transistor and the second transistor;
wherein the first gate and the second gate are respectively configured to receive a first signal and a second signal, and when the first transistor changes from a turned-on state to a turned-off state according to the first signal, the second transistor is in the turned-on state, and after the first transistor is in the turned-off state, the second transistor changes from the turned-on state to the turned-off state according to the second signal.

2. The component circuit according to claim 1, wherein the first transistor and the second transistor are electrically connected in series.

3. The component circuit according to claim 2, wherein the first transistor is coupled between the electronic component and the second transistor.

4. The component circuit according to claim 1, wherein the first transistor and the second transistor are electrically connected in parallel.

5. The component circuit according to claim 1, wherein the electronic component comprises a capacitor.

6. The component circuit according to claim 1, wherein the first signal is different from the second signal.

7. The component circuit according to claim 1, wherein the first transistor further comprises a first drain and a first source, the second transistor further comprises a second drain and a second source, the second drain of the second transistor is electrically connected to the first source of the first transistor, and the second source of the second transistor receives a third signal.

8. The component circuit according to claim 7, wherein the electronic component comprises a first terminal and a second terminal, the first terminal of the electronic component is electrically connected to the first drain of the first transistor, and the second terminal of the electronic component is electrically connected to a reference voltage.

9. The component circuit according to claim 1, wherein the first transistor further comprises a first drain and a first source, the second transistor further comprises a second drain and a second source, the first source of the first transistor is electrically connected to the second source of the second transistor and receives a third signal, and the first drain of the first transistor is electrically connected to the second drain of the second transistor.

10. The component circuit according to claim 9, wherein the electronic component comprises a first terminal and a second terminal, the first terminal of the electronic component is electrically connected to the first drain of the first transistor and the second drain of the second transistor, and the second terminal of the electronic component is electrically connected to a reference voltage.

11. An electronic device, comprising:
a first signal line, configured to provide a first signal, wherein the first signal line extends in a first direction;
a second signal line, configured to provide a second signal, wherein the second signal line extends in the first direction and is adjacent to the first signal line;
a third signal line, wherein the third signal line extends in a second direction, and the second direction is different from the first direction; and
a component circuit, electrically connected to the first signal line, the second signal line and the third signal line, wherein the component circuit comprises:
a first transistor, comprising a first gate;
a second transistor, comprising a second gate; and
an electronic component, electrically connected to the first transistor and the second transistor;
wherein the first gate and the second gate are respectively configured to receive the first signal and the second signal, and when the first transistor changes from a turned-on state to a turned-off state according to the first signal, the second transistor is in the turned-on state, and after the first transistor is in the turned-off state, the second transistor changes from the turned-on state to the turned-off state according to the second signal.

12. The electronic device according to claim 11, wherein the first transistor and the second transistor are electrically connected in series.

13. The electronic device according to claim 12, wherein the first transistor is coupled between the electronic component and the second transistor.

14. The electronic device according to claim 11, wherein the first transistor and the second transistor are electrically connected in parallel.

15. The electronic device according to claim 11, wherein the electronic component comprises a capacitor.

16. The electronic device according to claim 11, wherein the first signal is different from the second signal.

17. The electronic device according to claim 11, wherein the first transistor further comprises a first drain and a first source, the second transistor further comprises a second drain and a second source, the second drain of the second transistor is electrically connected to the first source of the first transistor, and the second source of the second transistor is electrically connected to the third signal line and receives the third signal provided by the third signal line.

18. The electronic device according to claim 17, wherein the electronic component comprises a first terminal and a second terminal, the first terminal of the electronic component is electrically connected to the first drain of the first transistor, and the second terminal of the electronic component is electrically connected to a reference voltage.

19. The electronic device according to claim 11, wherein the first transistor further comprises a first drain and a first source, the second transistor further comprises a second drain and a second source, the first source of the first transistor is electrically connected to the second source of the second transistor and the third signal line and receives the third signal provided by the third signal line, and the first drain of the first transistor is electrically connected to the second drain of the second transistor.

20. The electronic device according to claim 19, wherein the electronic component comprises a first terminal and a second terminal, the first terminal of the electronic component is electrically connected to the first drain of the first transistor and the second drain of the second transistor, and the second terminal of the electronic component is electrically connected to a reference voltage.
